(19) United States
(12) Patent Application Publication
(10) Pub. No.: US 2015/0146477 A1
(43) Pub. Date: May 28, 2015

(54) SEMICONDUCTOR DEVICE

(71) Applicant: RENESAS ELECTRONICS CORPORATION, Kawasaki-shi (JP)

(72) Inventors: Masaaki IIJIMA, Kanagawa (JP); Nguyen Thein, Ho Chi Minh City (VN)

(21) Appl. No.: 14/541,589

(22) Filed: Nov. 14, 2014

(30) Foreign Application Priority Data
Nov. 25, 2013 (JP) 2013-242954

(51) Int. Cl. G11C 11/4076

(52) U.S. Cl. CPC G11C 11/4076
USPC 365/154; 365/189.05

(57) ABSTRACT

In order to solve a problem that a calibration period for generating a signal obtained by delaying a core clock in a programmable manner is overhead in initialization, a clock generation circuit generates a plurality of delayed clocks having different phases by delaying a core clock which is an operation clock of a CPU, and selects a resynchronization clock whose phase is later than and closest to a phase of a data strobe signal from among the generated delayed clocks and the core clock.

### CROSS-REFERENCE TO RELATED APPLICATIONS

The disclosure of Japanese Patent Application No. 2013-242954 filed on Nov. 25, 2013 including the specification, drawings and abstract is incorporated herein by reference in its entirety.

### BACKGROUND

The present invention relates to a semiconductor device, and more particularly, to a semiconductor device that receives a data strobe signal and a data signal outputted from a memory.

In a DDR_PHY (DDR_PHYsical interface) in the related art, general architecture uses FIFO (First-In First-Out) for leveling in reading data from a DRAM (Dynamic Random Access Memory); however, there has been a problem that the provision of the FIFO for reading increases an area and a read latency. On the other hand, there has been proposed architecture that reduces the read latency and does not use the FIFO for reading.

For example, a DDR memory controller described in US patent No. 7975164B2 (Patent Document 1) latches a data signal DQ by a signal obtained by delaying a data strobe signal DQS, and again latches the latch output by a signal obtained by delaying a core clock in a programmable manner.

### SUMMARY

However, in the DDR memory controller described in Patent Document 1, a calibration period for generating the signal obtained by delaying the core clock in a programmable manner is overhead in initialization. Further, there is a possibility of taking noise due to no noise mask function after the postamble of the data strobe signal DQS. Further, there is a problem of not being able to align different input timings of the data signal DQ for different bits.

The other problems and novel features will become apparent from the description of this specification and the accompanying drawings.

According to one embodiment of the present invention, a clock generation circuit generates a plurality of delayed clocks having different phases by delaying a core clock which is an operation clock of a CPU, and selects a resynchronization clock whose phase is later than and closest to a phase of a data strobe signal from among the generated delayed clocks and the core clock.

According to the one embodiment of the present invention, it is possible to generate a clock for latching again a data signal latched by a data strobe signal, without causing overhead in initialization.

### BRIEF DESCRIPTION OF THE DRAWINGS

FIG. 1 is a diagram showing the configuration of a semiconductor device according to a first embodiment.

FIG. 2 is a diagram showing the configuration of a semiconductor device according to a second embodiment.

FIG. 3 is a diagram for explaining the configuration of a DDR_PHY.

FIG. 4 is a diagram showing the configuration of an RCLK generator.

FIG. 5 is a diagram showing the configuration of an edge detector.

FIG. 6 is a diagram showing the configuration of a selector.

FIG. 7 is a timing chart of a resynchronization candidate clock RCLKi, a resynchronization candidate clock latch signal RCLKi_r, and a resynchronization candidate clock preselection signal RCLKi_SEL_pre.

FIG. 8 is a timing chart of a calibration signal cal_en, calibration latch signals cal_en1 to cal_en8, calibration gate clocks cal_en_gck1 to cal_en_gck8, resynchronization candidate clocks RCLK1 to RCLK8, and resynchronization candidate clock selection signals RCLK1_SEL to RCLK8_SEL.

FIG. 9 is a diagram showing the configurations of a data enable controller and a capture register.

FIG. 10 is a timing chart of a resynchronization clock RCLK, a delay data strobe signal DQSd, a delay data signal DQd, a rise capture signal DQcpt_r, and a fall capture signal DQcpt_f.

FIG. 11 is a diagram showing the configurations of a resynchronization register and a leveling register.

FIG. 12 is a timing chart of the rise capture signal DQcpt_r, the resynchronization clock RCLK, the rise resynchronization signal DQrsc_r, a core clock CORE_CLK, and a signal rc in the case where a resynchronization selection signal resync_sel is at a low level.

FIG. 13 is a timing chart of the rise capture signal DQcpt_r, the resynchronization clock RCLK, the rise resynchronization signal DQrsc_r, the core clock CORE_CLK, and the signal rc in the case where the resynchronization selection signal resync_sel is at a high level.

FIG. 14 is a flowchart showing a procedure for calibration of the DDR_PHY.

FIG. 15 is a flowchart showing a detailed procedure of step S305 in FIG. 14.

FIG. 16 is a flowchart showing a detailed procedure of step S306 in FIG. 14.

FIG. 17 is a timing chart in the setting of selectors in the leveling register and in the calibration of the data signal DQ and the data strobe signal DQS.

FIG. 18 is a diagram for explaining an example of the delay amount of the data strobe signal DQS, a setup margin, and a hold margin.

FIG. 19 is a diagram for explaining another example of the delay amount of the data strobe signal DQS, the setup margin, and the hold margin.

### DETAILED DESCRIPTION

Hereinafter, embodiments of the present invention will be described with reference to the drawings.

### First Embodiment

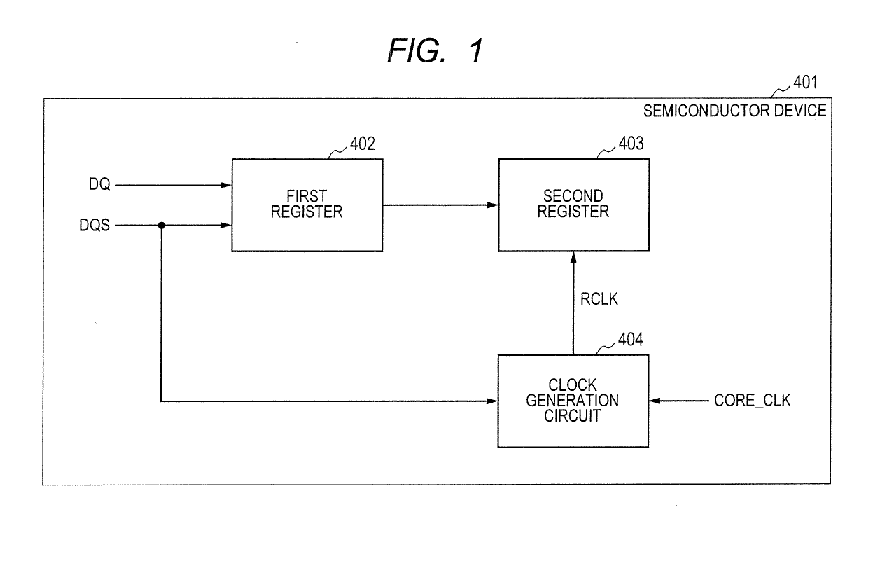

FIG. 1 is a diagram showing the configuration of a semiconductor device 401 according to the first embodiment.

The semiconductor device 401 includes a first register 402, a second register 403, and a clock generation circuit 404.

The first register 402 latches a data signal by a data strobe signal DQS.

The clock generation circuit 404 generates a resynchronization clock RCLK. The clock generation circuit generates a plurality of delayed clocks having different phases by delaying a core clock CORE_CLK which is an operation clock of a CPU, and selects the resynchronization clock RCLK whose phase is later than and closest to that of the data strobe signal DQS from among the generated delayed clocks and the core clock CORE_CLK. In this specification, whether the phase of a clock A is earlier or later than that of a clock B is determined based on the relationship between the timing ta of a rising edge of the clock A and the timing tb of a rising edge of the clock B having a difference of not more than π/2 from ta. In the case where ta<tb, the phase of the clock A is earlier than that of the clock B. In the case where ta>tb, the phase of the clock A is later than that of the clock B. The second register 403 latches the output data of the first register 402 by the resynchronization clock RCLK.

Thus, according to this embodiment, the output from the first register 402 which operates by the data strobe signal is resynchronized; therefore, it is possible to easily generate the clock having a small phase difference from the core clock CORE_CLK.

### Second Embodiment

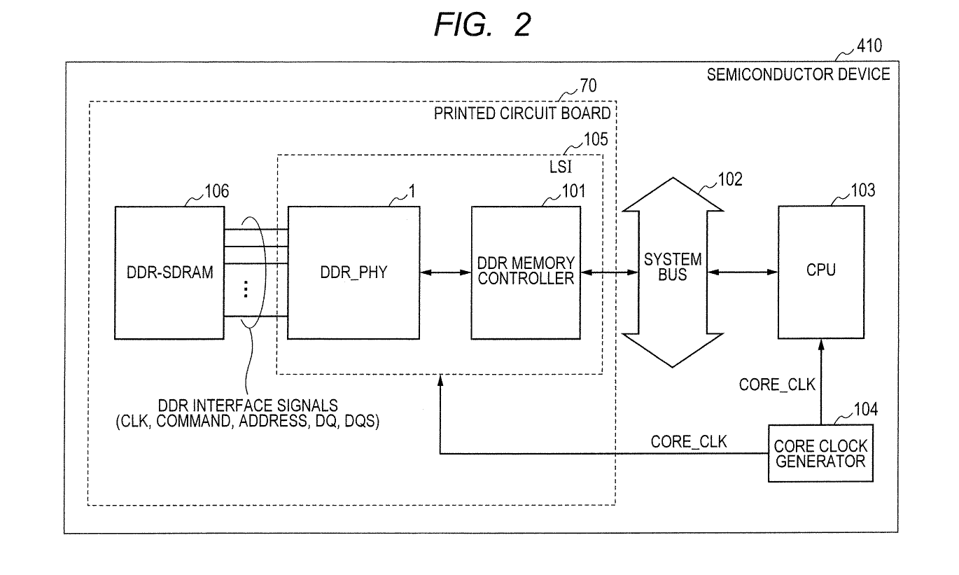

FIG. 2 is a diagram showing the configuration of a semiconductor device 410 according to the second embodiment.

The semiconductor device 410 includes a DDR-SDRAM (Double Data Rate-Synchronous Dynamic Random Access Memory) 106, a DDR_PHY 1, a DDR memory controller 101, a system bus 102, a CPU (Central Processing Unit) 103, and a core clock generator 104.

An LSI (Large Scale Integration) 105 and a DDR-SDRAM 106 are disposed over a printed circuit board 70. The DDR_PHY 1 and the DDR memory controller 101 are disposed in the LSI 105.

A clock CLK, a command, an address, a data signal DQ, and complementary data strobe signals DQS, DQSB exist as interface signals between the DDR_PHY 1 and the DDR-SDRAM 106.

The DDR-SDRAM 106 outputs data (read) and inputs data (write) at both the rising and falling edges of a synchronizing clock.

The DDR_PHY 1 converts parallel data from the DDR memory controller 101 into serial data and transmits the serial data to the DDR-SDRAM 106. The DDR_PHY 1 converts serial data from the DDR-SDRAM 106 into parallel data and transmits the parallel data to the DDR memory controller 101.

The DDR memory controller 101 controls the DDR-SDRAM 106. The system bus 102 is a bus for coupling the CPU 103 and the DDR memory controller 101.

The core clock generator 104 generates a core clock CORE_CLK. The CPU 103 instructs the reading of data from the DDR-SDRAM 106 and instructs the writing of data to the DDR-SDRAM 106.

The CPU 103, the DDR_PHY 1, the DDR memory controller 101, and some components of the DDR_PHY 1 operate with the core clock CORE_CLK.

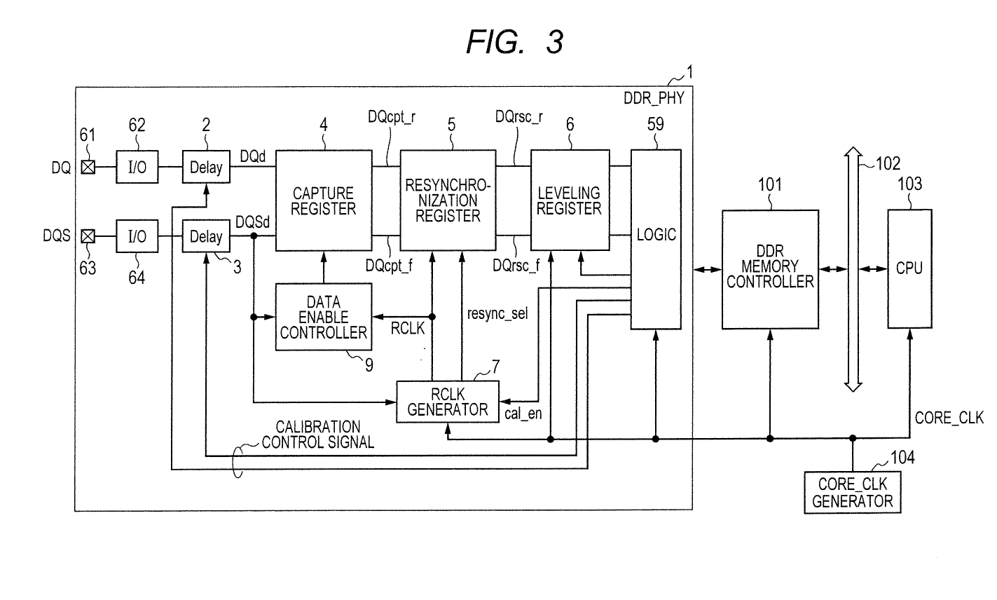

FIG. 3 is a diagram for explaining the configuration of the DDR_PHY 1. Referring to FIG. 3, the DDR_PHY 1 includes a DQ pad 61, a DQS pad 63, an I/O 62, an I/O 64, a delay circuit 2, a delay circuit 3, an RCLK generator 7, a data enable controller 9, a capture register 4, a resynchronization register 5, a leveling register 6, and a logic 59. The leveling register 6 and the logic 59 are includes in a core clock domain which operates with the core clock CORE_CLK.

The DQ pad 61 receives the data signal DQ outputted from the DDR-SDRAM 106. The DQS pad 63 receives the data strobe signal DQS outputted from the DDR-SDRAM 106.

The I/O 62 includes a single receiver circuit for comparing the data signal DQ with a predetermined reference voltage and outputting the comparison result. The I/O 64 includes a single receiver circuit for comparing the data strobe signal DQS with the predetermined reference voltage and outputting the comparison result.

The delay circuit 2 delays an output signal of the I/O 62 and outputs a delay data signal DQd. The delay circuit 3 delays an output signal of the I/O 64 and outputs a delay data strobe signal DQSd.

The RCLK generator 7 generates a plurality of delayed clocks RCLK2 to RCLK8 having different phases by delaying the core clock CORE_CLK, and processes the generated delayed clocks RCLK2 to RCLK8 and the core clock CORE_CLK (=RCLK1) as resynchronization candidate clocks. The RCLK generator 7 selects the resynchronization clock RCLK whose phase is later than and closest to that of the delay data strobe signal DQSd from among the resynchronization candidate clocks RCLK1 to RCLK8.

The capture register 4 latches the delay data signal DQd by the delay data strobe signal DQSd.

The data enable controller 9 generates a data enable signal data_en for controlling the latch of the data signal DQ in the capture register 4. The data enable controller 9 activates the data enable signal data_en to a high level, based on the resynchronization clock RCLK.

The resynchronization register 5 latches the output data of the capture register 4 by the resynchronization clock RCLK. The capture register 4 and the preceding stages perform processing synchronized with the delay data strobe signal DQSd, whereas the leveling register 6 and the subsequent stages perform processing synchronized with the core clock CORE_CLK. The resynchronization register 5 is used to resynchronize the output data of the capture register 4 to the core clock CORE_CLK.

The leveling register 6 is provided to adjust data read from the DDR-SDRAM 106 to the output timing of the DDR_PHY 1.

The logic 59 controls the reading of data from the DDR-SDRAM 106 in accordance with an instruction for reading data from the DDR-SDRAM 106 sent from the CPU 103.

The core clock CORE_CLK has the same period as the data strobe signal DQS.

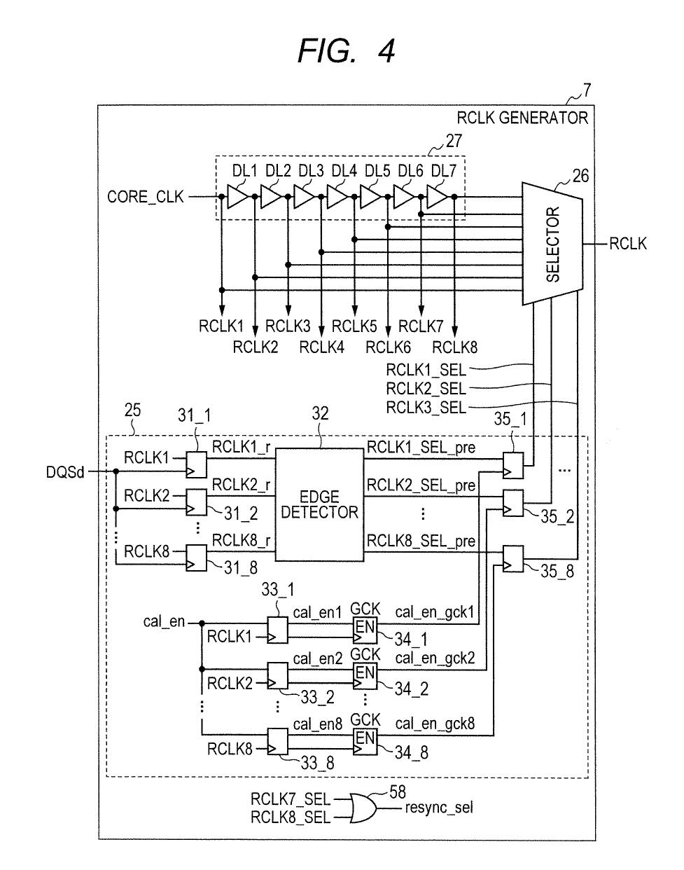

FIG. 4 is a diagram showing the configuration of the RCLK generator 7. The RCLK generator 7 includes a delay unit 27, a determination unit 25, a selector 26, and an OR circuit 58.

The delay unit 27 has a plurality of delay elements to which the core clock CORE_CLK is inputted.

The determination unit 25 determines an optimal clock whose phase is later than and closest to that of the delay data strobe signal DQSd from among the core clock CORE_CLK and respective clocks outputted from the delay elements.

The selector 26 selects the resynchronization clock RCLK from among the core clock CORE_CLK and the respective clocks outputted from the delay elements, based on the determination result.

The delay unit 27 receives the core clock CORE_CLK and outputs the eight resynchronization candidate clocks RCLK1 to RCLK8. The delay unit 27 includes seven delay circuits DL1 to DL7. The delay circuit DLi (i=1 to 7) delays an input signal by 45 degrees of the period of the core clock CORE_CLK.

The input of the first delay circuit DL1, that is, the core clock CORE_CLK is outputted as the first resynchronization candidate clock RCLK1. The delay circuit DLi (i=1 to 7) outputs the (i+1)th resynchronization candidate clock RCLKi+1.

The determination unit 25 includes flip-flops 31_1 to 31_8, an edge detector 32, flip-flops 35_1 to 35_8, clock gates 34_1 to 34_8, flip-flops 33_1 to 33_8, and an OR circuit 58.

The flip-flop 31_{—}i (i=1 to 8) is provided corresponding to the ith resynchronization candidate clock RCLKi.

The ith resynchronization candidate clock RCLKi is inputted to the data input terminal of the flip-flop 31_{—}i (i=1 to 8). The delay data strobe signal DQSd is inputted to the clock terminal of the flip-flop 31_{—}i. The flip-flop 31_{—}i latches the ith resynchronization candidate clock RCLKi at the rising timing of the delay data strobe signal DQSd, and outputs the ith resynchronization candidate clock latch signal RCLKi_r.

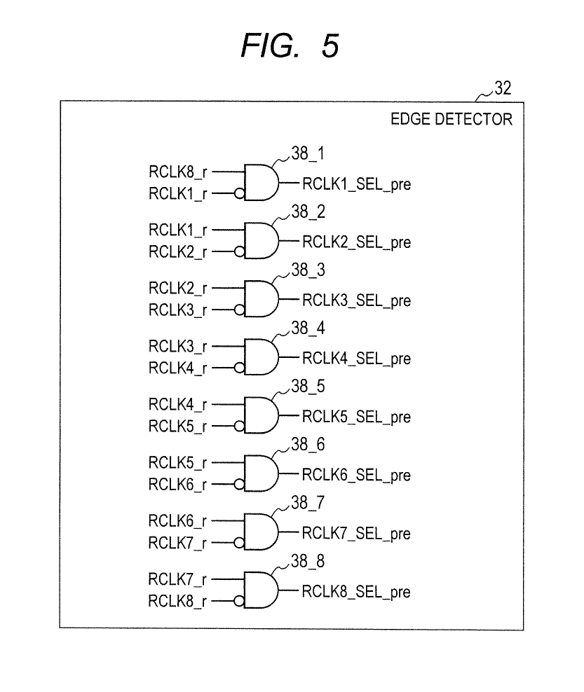

FIG. 5 is a diagram showing the configuration of the edge detector 32. As shown in FIG. 5, the edge detector 32 includes logic circuits 38_1 to 38_8.

The logic circuit 38_1 outputs the logical AND between the inverted clock of the first resynchronization candidate clock latch signal RCLK1_{—}r and the eighth resynchronization candidate clock latch signal RCLK8_{—}r, as a first resynchronization candidate clock preselection signal RCLK1_SEL_pre.

The logic circuit 38_{—}i (i=2 to 8) outputs the logical AND between the inverted clock of the ith resynchronization candidate clock latch signal RCLKi_r and the (i−1)th resynchronization candidate clock latch signal RCLKi-1_{—}r, as the ith resynchronization candidate clock preselection signal RCLKi_SEL_pre.

In the edge detector 32, when RCLKi-l_{—}r is at a high level and RCLKi_r is at a low level, RCLKi_SEL_pre becomes the high level. That is, a point (edge) where the high level changes to the low level in the level changes from RCLK1_{—}r to RCLK2_{—}r to . . . to RCLK8_{—}r to RCLK1_{—}r is detected. Thereby, it is possible to select an optimal clock whose phase is later than and closest to that of the delay data strobe signal DQSd. This can prevent a setup time and a hold time from leaning to one side.

The ith resynchronization candidate clock RCLKi is inputted to the clock terminal of the flip-flop 33_{—}i (i=1 to 8). A calibration signal cal_en for instructing calibration enabling is inputted to the data input terminal of the flip-flop 33_{—}i. The flip-flop 33_{—}i outputs the ith calibration latch signal cal_eni.

The ith calibration latch signal cal_eni is inputted to the enable terminal of the clock gate 34_{—}i (i=1 to 8). The ith resynchronization candidate clock RCLKi is inputted to the clock terminal of the clock gate 34_{—}i. When the ith calibration latch signal cal_eni is at the high level, the clock gate 34_{—}i outputs the inputted ith resynchronization candidate clock RCLKi as the ith calibration gate clock cal_en_gcki.

The flip-flop 35_{—}i (i=1 to 8) is provided corresponding to the ith resynchronization candidate clock RCLKi.

The ith calibration gate clock cal_en_gcki is inputted to the clock terminal of the flip-flop 35_{—}i (i=1 to 8). The ith resynchronization candidate clock preselection signal RCLKi_SEL_pre is inputted to the data input terminal of the flip-flop 35_{—}i. The flip-flop 35_{—}i outputs the ith resynchronization candidate clock selection signal RCLKi_SEL. The flip-flop 35_{—}i latches the high level (first level) if the corresponding ith resynchronization candidate clock RCLKi is the optimal clock, and latches the low level (second level) if the corresponding ith resynchronization candidate clock RCLKi is not the optimal clock.

The selector receives the outputs of the flip-flops 35_1 to 35_8, and selects the resynchronization candidate clock corresponding to the flip-flop that outputs the high level, as the resynchronization clock RCLK.

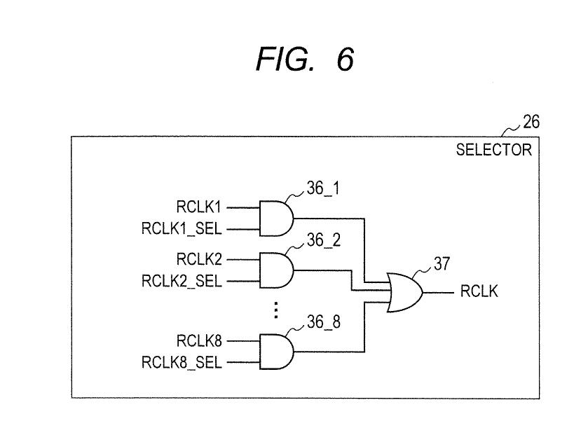

FIG. 6 is a diagram showing the configuration of the selector 26. As shown in FIG. 6, the selector 26 includes AND circuits 36_1 to 36_8 and an OR circuit 37.

The AND circuit 36_{—}i (i=1 to 8) outputs the logical AND between the ith resynchronization candidate clock RCLKi and the ith resynchronization candidate clock selection signal RCLKi_SEL.

The OR circuit 37 outputs the logical OR among the outputs of the AND circuits 36_1 to 36_8 as the resynchronization clock RCLK.

Referring again to FIG. 4, the OR circuit 58 outputs the logical OR between the seventh resynchronization candidate clock selection signal RCLK7_SEL and the eighth resynchronization candidate clock selection signal RCLK8_SEL, as a resynchronization selection signal resync_sel. That is, if the seventh resynchronization candidate clock RCLK7 or the eighth resynchronization candidate clock RCLK8 is selected as the resynchronization clock RCLK, the resynchronization selection signal resync_sel becomes the high level. If another resynchronization candidate clock is selected as the resynchronization clock RCLK, the resynchronization selection signal resync_sel becomes the low level. The seventh resynchronization candidate clock RCLK7 and the eighth resynchronization candidate clock RCLK8 are predetermined clocks whose phases are earlier than and slightly different from that of the core clock CORE_CLK.

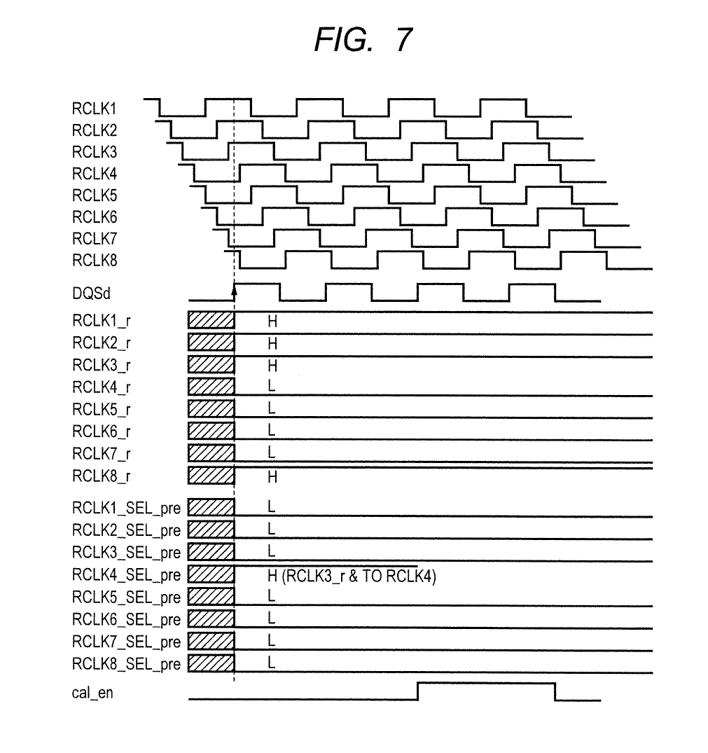

FIG. 7 is a timing chart of the resynchronization candidate clock RCLKi, the resynchronization candidate clock latch signal RCLKi_r, and the resynchronization candidate clock preselection signal RCLKi_SEL_pre.

As shown in FIG. 7, the RCLK generator 7 outputs the eight resynchronization candidate clocks RCLK1 to RCLK8.

The flip-flops 31_1 to 31_3 and 31_8 latch the resynchronization candidate clocks RCLK1 to RCLK3 and RCLK8 of the high level at the rising edge of the delay data strobe signal DQSd, and output resynchronization candidate clock latch signals RCLK1_{—}r to RCLK3_{—}r and RCLK8_{—}r of the high level. The flip-flops 31_4 to 31_7 latch the resynchronization candidate clocks RCLK4 to RCLK7 of the low level at the rising edge of the delay data strobe signal DQSd, and output resynchronization candidate clock latch signals RCLK4_{—}r to RCLK7_{—}r of the low level.

Since the third resynchronization candidate clock latch signal RCLK3_{—}r is at the high level and the fourth resynchronization candidate clock latch signal RCLK4_{—}r is at the low level, by the edge detector 32 the fourth resynchronization candidate clock preselection signal RCLK4_SEL_pre becomes the high level.

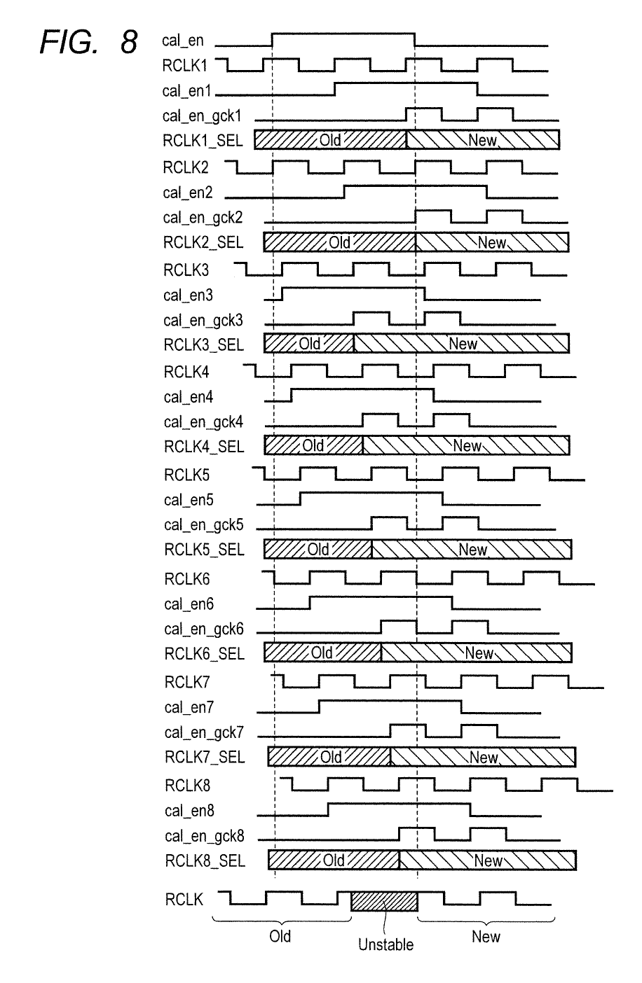

FIG. 8 is a timing chart of the calibration signal cal_en, the calibration latch signals cal_en1 to cal_en8, the calibration gate clocks cal_en_gck1 to cal_en_gck8, the resynchronization candidate clocks RCLK1 to RCLK8, and the resynchronization candidate clock selection signals RCLK1_SEL to RCLK8_SEL.

The flip-flop 33_{—}i latches the calibration signal cal_en of the high level or the low level at the rising edge of RCLKi, and outputs the ith calibration latch signal cal_eni of the high level or the low level.

The clock gate 34_{—}i outputs the ith resynchronization candidate clock RCLKi as the ith calibration gate clock cal_en_gcki when the ith calibration latch signal cal_eni is at the high level.

At the time of calibration (when cal_en is at the high level), the phase of the delay data strobe signal DQSd changes; accordingly, the ith resynchronization candidate clock latch signal RCLKi_r and the ith resynchronization candidate clock preselection signal RCLKi_SEL_pre also change.

The ith resynchronization candidate clock selection signal RCLKi_SEL is updated at the first rising timing of the ith calibration gate clock cal_en_gcki.

Thereby, after the calibration signal cal_en is set to the low level, the resynchronization clock RCLK is updated when the resynchronization candidate clock RCLKi first rises.

While a glitch might occur in the resynchronization clock RCLK when the ith resynchronization candidate clock selection signal RCLKi_SEL is changed, this update operation is executed only in an initialization sequence, which does not affect a normal read operation.

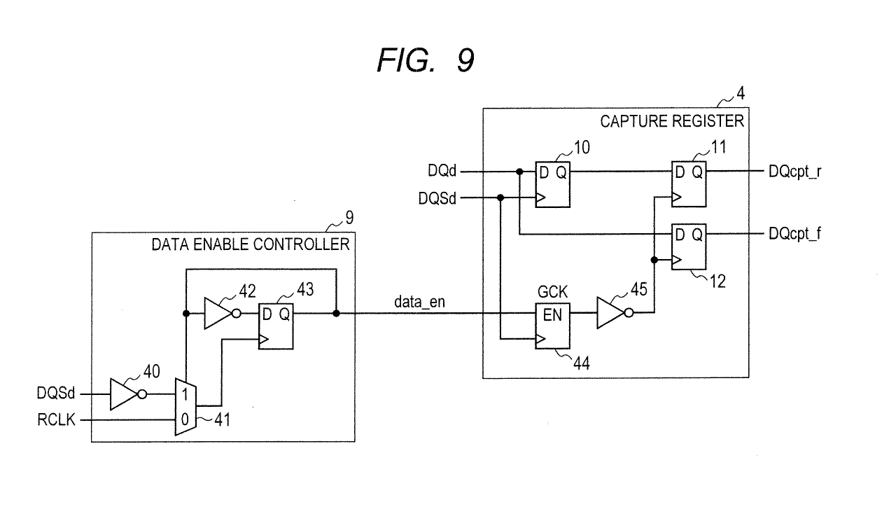

FIG. 9 is a diagram showing the configurations of the data enable controller 9 and the capture register 4.

As shown in FIG. 9, the data enable controller 9 includes an inverter 40, a selector 41, an inverter 42, and a flip-flop 43.

The inverter 40 receives the delay data strobe signal DQSd and sends the inverted signal of the delay data strobe signal DQSd to the selector 41. The selector 41 receives the inverted signal of the delay data strobe signal DQSd and the resynchronization clock RCLK. The selector 41 outputs the inverted signal of the delay data strobe signal DQSd when the data enable signal data_en is at the high level, and outputs the resynchronization clock RCLK when the data enable signal data_en is at the low level.

The inverter 42 receives the data enable signal data_en and outputs the inverted signal of the data enable signal data_en.

The output of the selector 41, that is, the inverted signal of the delay data strobe signal DQSd or the resynchronization clock RCLK is inputted to the clock terminal of the flip-flop 43. The output of the inverter 42, that is, the inverted signal of the data enable signal data_en is inputted to the data input terminal of the flip-flop 43. The flip-flop 43 outputs the data enable signal data_en.

If the data enable signal data_en is at the low level, the data enable signal data_en is activated to the high level at the rising timing of the resynchronization clock RCLK. If the data enable signal data_en is at the high level, the data enable signal data_en is deactivated to the low level at the falling timing of the delay data strobe signal DQSd.

The capture register 4 includes a clock gate 44, an inverter 45, and flip-flops 10 to 12.

The data enable signal data_en is inputted to the enable terminal of the clock gate 44. The delay data strobe signal DQSd is inputted to the clock terminal of the clock gate 44. The clock gate 44 outputs the inputted delay data strobe signal DQSd to the inverter 45 when the data enable signal data_en is at the high level.

The inverter 45 receives the delay data strobe signal DQSd which is the output signal of the clock gate 44, and outputs the inverted signal of the delay data strobe signal DQSd.

The delay data strobe signal DQSd is inputted to the clock terminal of the flip-flop 10. The delay data signal DQd is inputted to the data input terminal of the flip-flop 10. The output of the flip-flop 10 is sent to the flip-flop 11.

The output signal of the inverter 45 is inputted to the clock terminal of the flip-flop 11. The output signal of the flip-flop 10 is inputted to the data input terminal of the flip-flop 11. The flip-flop 11 outputs a rise capture signal DQcpt_r.

The output signal of the inverter 45 is inputted to the clock terminal of the flip-flop 12. The delay data signal DQd is inputted to the data input terminal of the flip-flop 12. The flip-flop 12 outputs a fall capture signal DQcpt_f.

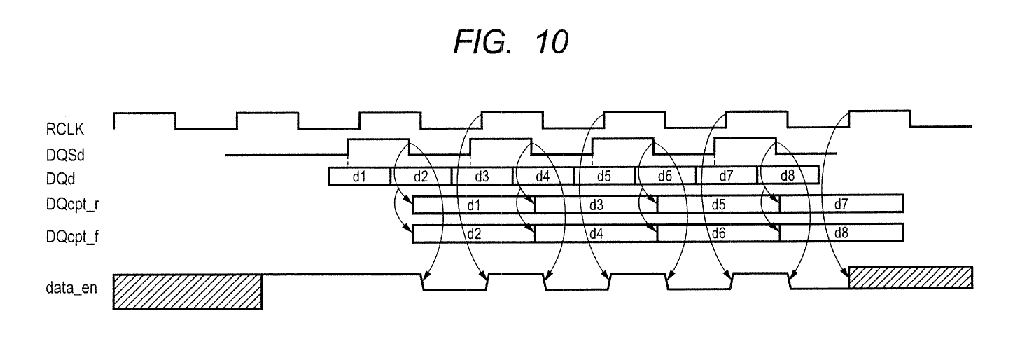

FIG. 10 is a timing chart of the resynchronization clock RCLK, the delay data strobe signal DQSd, the delay data signal DQd, the rise capture signal DQcpt_r, and the fall capture signal DQcpt_f.

When the data enable signal data_en which is the output of the flip-flop 43 is at the high level, the selector 41 outputs the output of the inverter 40 to the clock terminal of the flip-flop 43; therefore, the data enable signal data_en falls at the falling timing of the delay data strobe signal DQSd.

On the other hand, when the data enable signal data_en which is the output of the flip-flop 43 is at the low level, the selector 41 outputs the resynchronization clock RCLK to the clock terminal of the flip-flop 43; therefore, the data enable signal data_en rises at the rising timing of the resynchronization clock RCLK.

The flip-flop 10 latches the delay data signal DQd at the rising timing of the delay data strobe signal DQSd. Further, the flip-flop 11 latches the output of the flip-flop 10 and the flip-flop 12 latches the delay data signal DQd at the falling timing of the delay data strobe signal DQSd when the data enable signal data_en is at the high level.

Therefore, the rise capture signal DQcpt_r which is the output of the flip-flop 11 carries delay data signals dl, d3, d5, d7 . . . at the falling timings of the delay data strobe signal DQSd when the data enable signal data_en is at the high level. Further, the fall capture signal DQcpt_f which is the output of the flip-flop 12 carries delay data signals d2, d4, d6, d8 . . . at the rising timings of the delay data strobe signal DQSd when the data enable signal data_en is at the high level.

The data enable signal data_en is activated based on the resynchronization clock RCLK, and is not activated by the data strobe signal DQS. This can prevent the data enable signal data_en to be erroneously activated when the data strobe signal DQS becomes unstable after postamble.

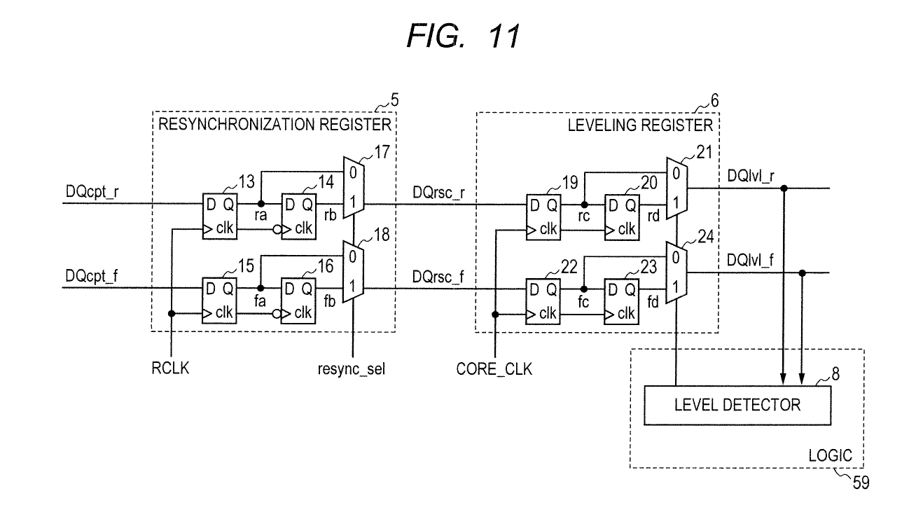

FIG. 11 is a diagram showing the configurations of the resynchronization register 5 and the leveling register 6. As shown in FIG. 11, the resynchronization register 5 includes flip-flops 13 to 16 and selectors 17 and 18.

The resynchronization clock RCLK is inputted to the clock terminal of the flip-flop 13. The rise capture signal DQcpt_r is inputted to the data input terminal of the flip-flop 13. An output signal ra of the flip-flop 13 is sent to the flip-flop 14 and the selector 17.

The resynchronization clock RCLK is inputted to the clock terminal of the flip-flop 15. The fall capture signal DQcpt_f is inputted to the data input terminal of the flip-flop 15. output signal fa of the flip-flop 15 is sent to the flip-flop 16 and the selector 18.

The resynchronization clock RCLK is inputted to the clock terminal of the flip-flop 14. The output signal ra of the flip-flop 13 is inputted to the data input terminal of the flip-flop 14. An output signal rb of the flip-flop 14 is sent to the selector 17.

The resynchronization clock RCLK is inputted to the clock terminal of the flip-flop 16. The output signal fa of the flip-flop 15 is inputted to the data input terminal of the flip-flop 16. An output signal fb of the flip-flop 16 is sent to the selector 18.

The selector 17 receives the output signal ra of the first stage flip-flop 13 and the output signal rb of the second stage flip-flop 14. When the resynchronization selection signal resync_sel is at the high level, the selector 17 outputs the signal rb as a rise resynchronization signal DQrsc_r. When the resynchronization selection signal resync_sel is at the low level, the selector 17 outputs the signal ra as the rise resynchronization signal DQrsc_r. That is, if the seventh resynchronization candidate clock RCLK7 or the eighth resynchronization candidate clock RCLK8 whose phase is earlier than and slightly different from that of the core clock CORE_CLK is selected as the resynchronization clock RCLK, the output signal rb of the second stage flip-flop 14 is outputted. This is because it might not be possible to secure a setup time in the subsequent leveling register 6 if the signal ra is outputted to the subsequent leveling register 6; therefore, the signal rb obtained by delaying the signal ra by half the period is outputted to the subsequent leveling register 6. If another resynchronization candidate clock RCLK1 to RCK6 is selected as the resynchronization clock RCLK, the output signal ra of the first stage flip-flop 13 is outputted.

The selector 18 receives the output signal fa of the first stage flip-flop 15 and the output signal fb of the second stage flip-flop 16. When the resynchronization selection signal resync_sel is at the high level, the selector 18 outputs the signal fb as a fall resynchronization signal DQrsc_f. When the resynchronization selection signal resync_sel is at the low level, the selector 18 outputs the signal fa as the fall resynchronization signal DQrsc_f. That is, if the seventh resynchronization candidate clock RCLK7 or the eighth resynchronization candidate clock RCLK8 whose phase is earlier than and slightly different from that of the core clock CORE_CLK is selected as the resynchronization clock RCLK, the output signal fb of the second stage flip-flop 16 is outputted. This is because it might not be possible to secure a setup time in the subsequent leveling register 6 if the signal fa is outputted to the subsequent leveling register 6; therefore, the signal fb obtained by delaying the signal fa by half the period is outputted to the subsequent leveling register 6. If another resynchronization candidate clock RCLK1 to RCK6 is selected as the resynchronization clock RCLK, the output signal fa of the first stage flip-flop 15 is outputted.

As shown in FIG. 11, the leveling register 6 includes flip-flops 19 to 23 and selectors 21 and 24.

The core clock CORE_CLK is inputted to the clock terminal of the flip-flop 19. The rise resynchronization signal DQrsc_r is inputted to the data input terminal of the flip-flop 19. An output signal rc of the flip-flop 19 is sent to the flip-flop 20 and the selector 21.

The core clock CORE_CLK is inputted to the clock terminal of the flip-flop 22. The fall resynchronization signal DQrsc_f is inputted to the data input terminal of the flip-flop 22. An output signal fc of the flip-flop 22 is sent to the flip-flop 23 and the selector 24.

The core clock CORE_CLK is inputted to the clock terminal of the flip-flop 20. The output signal rc of the flip-flop 19 is inputted to the data input terminal of the flip-flop 20. An output signal rd of the flip-flop 20 is sent to the selector 21.

The core clock CORE_CLK is inputted to the clock terminal of the flip-flop 23. The output signal fc of the flip-flop 22 is inputted to the data input terminal of the flip-flop 23. An output signal fd of the flip-flop 23 is sent to the selector 24.

The selector 21 receives the output signal rc of the first stage flip-flop 19 and the output signal rd of the second stage flip-flop 20. When a signal from a level detector 8 is at the high level, the selector 21 outputs the signal rd as a rise leveling signal DQlv1_{—}r. When the signal from the level detector 8 is at the low level, the selector 21 outputs the signal rc as the rise leveling signal DQlv1_{—}r.

The selector 24 receives the output signal fc of the first stage flip-flop 22 and the output signal fd of the second stage flip-flop 23. When the signal from the level detector 8 is at the high level, the selector 24 outputs the signal fd as a fall leveling signal DQlv1_{—}f. When the signal from the level detector 8 is at the low level, the selector 24 outputs the signal fc as the fall leveling signal DQlv1_{—}f.

The level detector 8 detects the levels of the rise leveling signal DQlv1_{—}r and the fall leveling signal DQlv1_{—}f outputted from the leveling register 6, and controls the selection by the selectors 21 and 24, based on the detection result.

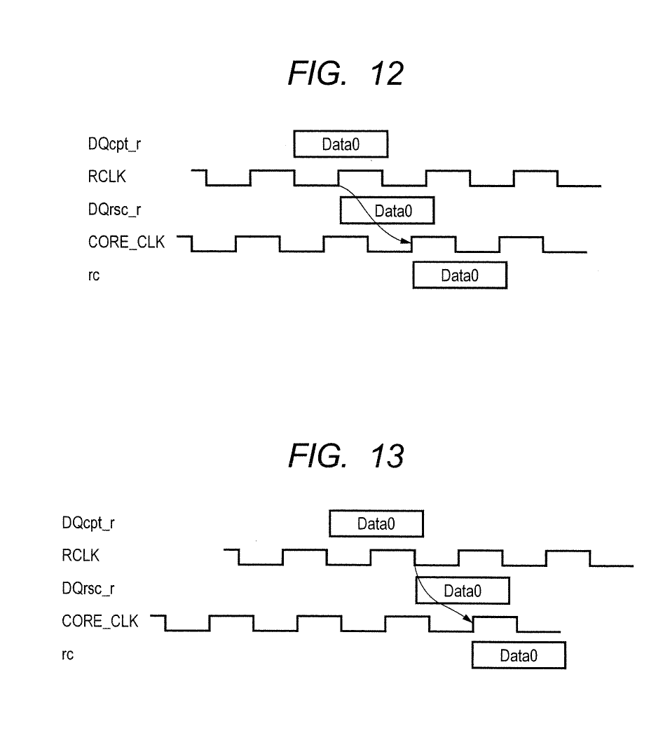

FIG. 12 is a timing chart of the rise capture signal DQcpt_r, the resynchronization clock RCLK, the rise resynchronization signal DQrsc_r, the core clock CORE_CLK, and the signal rc in the case where the resynchronization selection signal resync_sel is at the low level.

The flip-flop 13 latches the rise capture signal DQcpt_r for carrying data0 at the rising edge of the resynchronization clock RCLK.

If any of the first resynchronization candidate clock RCLK1 to the sixth resynchronization candidate clock RCLK6 is selected as the resynchronization clock RCLK, the resynchronization selection signal resync_sel becomes the low level. When the resynchronization selection signal resync_sel is at the low level, the selector 17 selects and outputs the output signal ra of the flip-flop 13 as the rise resynchronization signal DQrsc_r. Then, the flip-flop 19 latches the rise resynchronization signal DQrsc_r for carrying data0 at the next rising edge of the core clock CORE_CLK, and outputs the signal rc.

Because the phases of the first resynchronization candidate clock RCLK1 to the sixth resynchronization candidate clock RCLK6 are later than that of the core clock CORE_CLK or the phases of the first resynchronization candidate clock RCLK1 to the sixth resynchronization candidate clock RCLK6 are earlier than and largely different from that of the core clock CORE_CLK, the selector 17 selects the output signal ra of the flip-flop 13. In such a case, the flip-flop 19 can correctly latch the output signal ra of the flip-flop 13 at the next rising edge of the core clock CORE_CLK.

FIG. 13 is a timing chart of the rise capture signal DQcpt_r, the resynchronization clock RCLK, the rise resynchronization signal DQrsc_r, the core clock CORE_CLK, and the signal rc in the case where the resynchronization selection signal resync_sel is at the high level.

The flip-flop 13 latches the rise capture signal DQcpt_r for carrying data0 at the rising edge of the resynchronization clock RCLK. The flip-flop 14 latches the rise capture signal DQcpt_r for carrying data0 at the next falling edge of the resynchronization clock RCLK.

If the seventh resynchronization candidate clock RCLK7 or the eighth resynchronization candidate clock RCLK8 is selected as the resynchronization clock RCLK, the resynchronization selection signal resync_sel becomes the high level. When the resynchronization selection signal resync_sel is at the high level, the selector 17 selects and outputs the output signal rb of the flip-flop 14 as the rise resynchronization signal DQrsc_r. Then, the flip-flop 19 latches the rise resynchronization signal DQrsc_r for carrying data° at the next rising edge of the core clock CORE_CLK, and outputs the signal rc.

The seventh resynchronization candidate clock RCLK7 and the eighth resynchronization candidate clock RCLK8 are clocks whose phases are earlier than and slightly different from that of the core clock CORE_CLK. Accordingly, the flip-flop 19 might not be able to latch the output signal ra of the flip-flop 13 at the next rising edge of the core clock CORE_CLK if the output signal ra of the flip-flop 13 is outputted to the leveling register 6 as shown in FIG. 12; therefore, the selector 17 selects the output signal rb of the flip-flop 14.

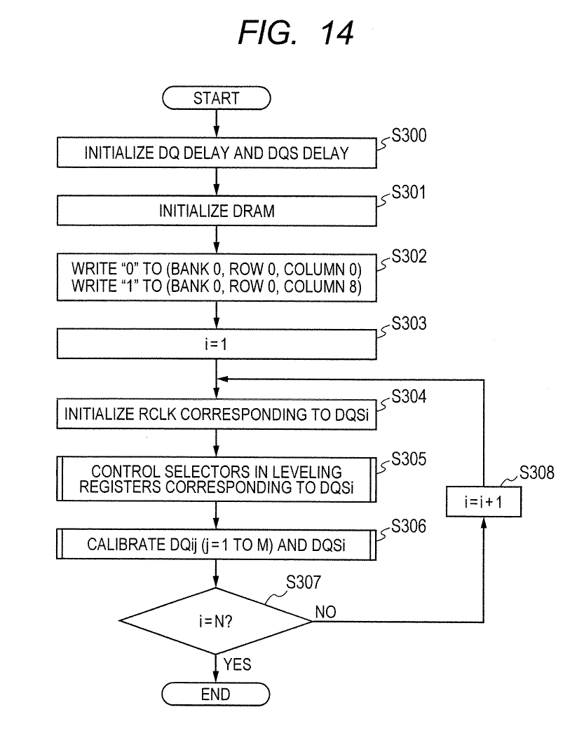

FIG. 14 is a flowchart showing a procedure for calibration of the DDR_PHY 1.

In FIG. 14, assume that a data strobe signal DQSi (i=1 to N) and a data signal DQij (i=1 to N, j=1 to M) are inputted to the DDR_PHY 1, one data strobe signal DQSi corresponds to M data signals DQij (j=1 to M), and the M data signals DQij (j=1 to M) are latched by the data strobe signal DQSi.

The RCLK generator 7 is provided for each data strobe signal DQSi. Therefore, N RCLK generators 7 are provided. The logic 59 is provided in common to all data strobe signals DQSi and data signals DQij.

In step S300, the logic 59 sets the delay amount of the delay circuit 2 and the delay amount of the delay circuit 3 to an initial value which is, for example, half the maximum delay amount of the delay circuit 2 or the delay circuit 3.

In step S301, the DDR memory controller 101 and the logic 59 initialize the DDR-SDRAM 106.

In step S302, the DDR memory controller 101 and the logic 59 write all “0” and all “1” to different columns of the same bank and the same row in the DDR-SDRAM 106 beforehand. More specifically, all “0” is written to (bank 0, row 0, column 0), and all “1” is written to (bank 0, row 0, column 8). The data written beforehand is used in later-described calibration.

In step S303, a variable i is set to 1. In step S304, the DDR memory controller 101 and the logic 59 initialize the resynchronization clock RCLK outputted from the RCLK generator 7 which receives the delay data strobe signal DQSdi. First, the DDR memory controller 101 successively issues a read command so that the delay data strobe signal DQSdi is successively outputted from the DDR-SDRAM 106 to the DDR_PHY 1. Based on the successively inputted delay data strobe signal DQSdi, the RCLK generator 7 selects the resynchronization clock RCLK from among the resynchronization candidate clocks RCLK1 to RCLK8. The logic 59 activates the calibration signal ca1_en to the high level after a lapse of sufficient time from the successive issue of the read command. The RCLK generator 7 updates the selected resynchronization clock RCLK while the calibration signal cal_en is activated.

In step S305, the level detector 8 determines the levels of the rise leveling signals DQlv1_{—}r and the fall leveling signals DQlv1_{—}f outputted from M leveling registers 6 corresponding to the data strobe signal DQSi, and controls the selection by the selectors 21 and 24 in the leveling registers 6, based on the determination result.

In step S306, the DDR memory controller 101 and the logic 59 calibrate the M data signals DQij (j=1 to M) and the data strobe signal DQSi. The M delay circuits 2 which receive the M data signals DQij (j=1 to M) and the delay circuit 3 which receives the data strobe signal DQSi are optimized.

In step S307 if i is equal to N, the process ends. If i is not equal to N, the flow proceeds to step S308.

In step S308, i is incremented, and the flow returns to step S304.

By step S305, even if interconnection lengths for transmitting the data signals DQij (j=1 to M) are different from each other, output timings of the data signals DQij from the DDR_PHY 1 are aligned with each other.

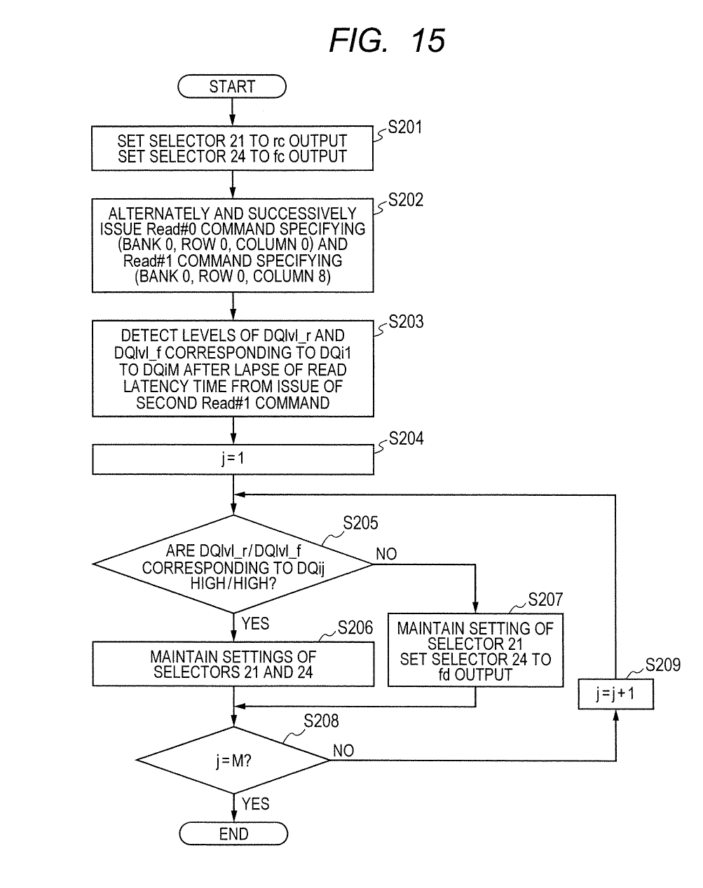

FIG. 15 is a flowchart showing a procedure for controlling the selection by the selectors 21 and 24 in the M leveling registers 6 corresponding to DQSi shown in step S305 in FIG. 14.

In step S201, the logic 59 sets the selector 21 in the M leveling registers 6 to output the output signal rc of the flip-flop 19 and sets the selector 24 to output the output signal fc of the flip-flops 22.

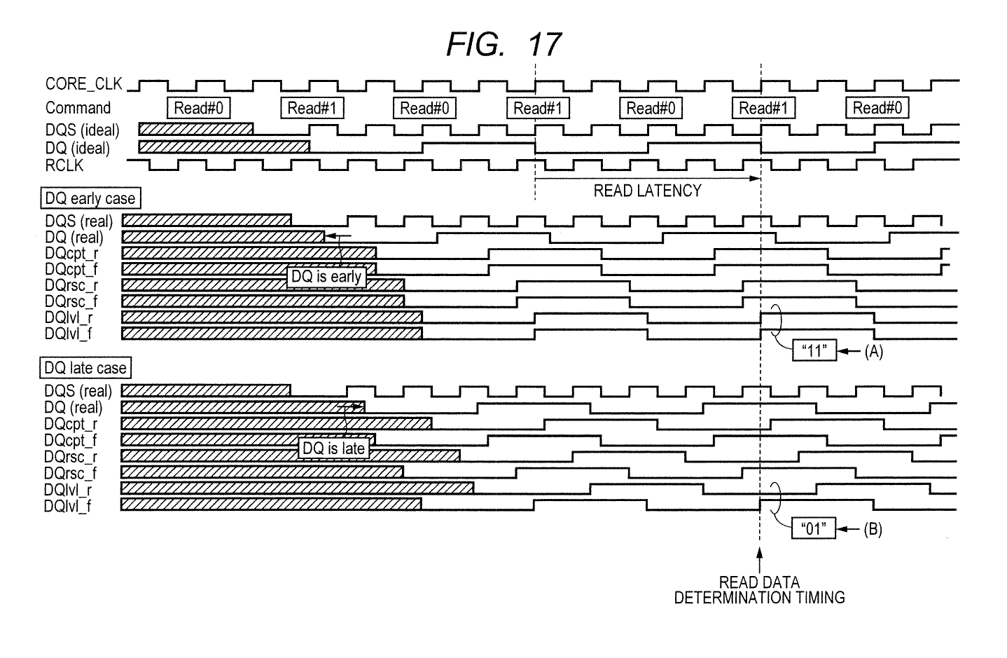

In step S202, the DDR memory controller 101 and the logic 59 alternately and successively issue a Read #0 command which specifies the address of (bank 0, row 0, column 0) storing all “0” and a Read #1 command which specifies the address of (bank 0, row 0, column 8) storing all “1”, as shown in FIG. 17.

In step S203, the level detector 8 in the logic 59 detects the levels of the rise leveling signal DQlv1_{—}r and the fall leveling signal DQlv1_{—}f outputted from the leveling register 6 corresponding to the data signal DQij after a lapse of a predetermined read latency time from the issue of the second Read #1 command.

In step S204, a variable j is set to 1. In step S205 if the rise leveling signal DQlv1_{—}r is at the high level and the fall leveling signal DQlv1_{—}f is at the high level as shown by (A) in FIG. 17, all “1” is read correctly and the flow proceeds to step S206. If the rise leveling signal DQlv1_{—}r is at the low level and the fall leveling signal DQlv1_{—}f is at the high level as shown by (B) in FIG. 17, all “1” is not read correctly and the flow proceeds to step S207. Further, logically possible cases where the rise leveling signal DQlv1_{—}r is at the high level and the fall leveling signal DQlv1_{—}f is at the low level and where the rise leveling signal DQlv1_{—}r is at the low level and the fall leveling signal DQlv1_{—}f is at the low level do not actually occur.

In step S206, the logic 59 maintains the setting of the selector 21 and the setting of the selector 24. Consequently, the selector 21 maintains the output signal rc of the flip-flop 19, and the selector 24 maintains the output signal fc of the flip-flop 22.

In step S207, the logic 59 maintains the setting of the selector 21 and sets the selector 24 to output the output signal fd of the flip-flop 23.

In step S208 if the variable j is equal to M, the process ends. If the variable j is not equal to M, the flow proceeds to step S209.

In step S209, the variable j is incremented, and the flow returns to step S205.

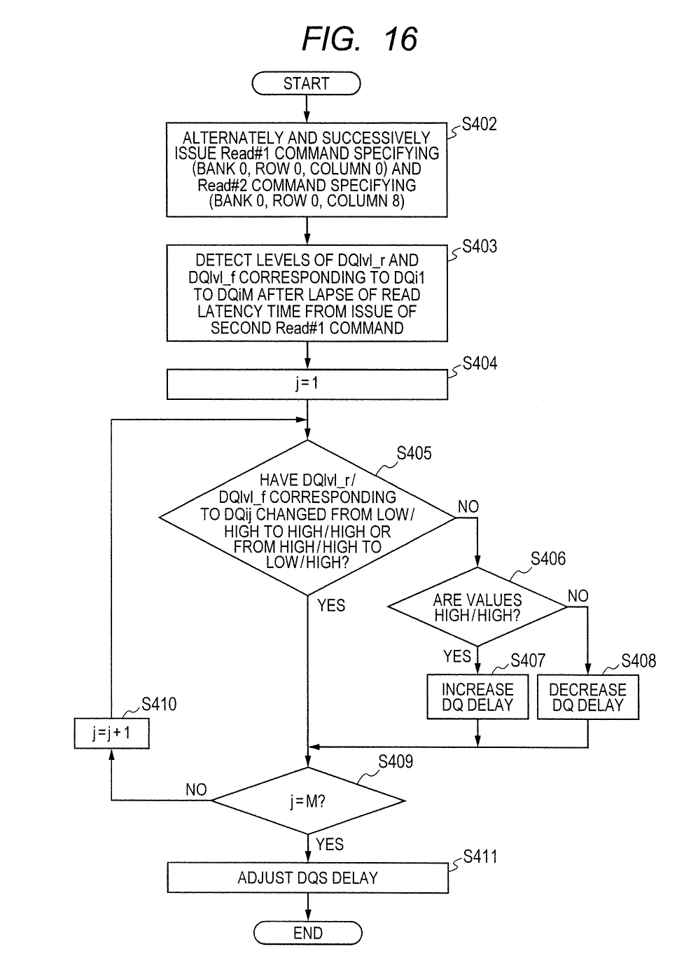

FIG. 16 is a flowchart showing a procedure for calibrating the data signals DQij (j=1 to M) and the data strobe signal DQSi shown in step S306 in FIG. 14.

In step S402, the DDR memory controller 101 and the logic 59 alternately and successively issue the Read #0 command which specifies the address of (bank 0, row 0, column 0) storing all “0” and the Read #1 command which specifies the address of (bank 0, row 0, column 8) storing all “1”, as shown in FIG. 17.

In step S403, the level detector 8 in the logic 59 detects the levels of the rise leveling signal DQlv1_{—}r and the fall leveling signal DQlv1_{—}f outputted from the leveling register 6 corresponding to the data signal DQij after a lapse of a predetermined read latency time from the issue of the second Read #1 command.

In step S404, the variable j is set to 1. In step S405 if the previous rise leveling signal DQlv1_{—}r is at the low level, the previous fall leveling signal DQlv1_{—}f is at the high level, the current rise leveling signal DQlv1_{—}r is at the high level, and the current fall leveling signal DQlv1_{—}f is at the high level, the flow proceeds to step S409. In this case, as shown by (A) in FIG. 17, the rise leveling signal DQlv1_{—}r and the fall leveling signal DQlv1_{—}f rise at the timing of the read latency; therefore, the delay amount of the data signal DQij is set properly, so that the delay amount of the data signal DQij is not set.

Further, if the previous rise leveling signal DQlv1_{—}r is at the high level, the previous fall leveling signal DQlv1_{—}f is at the high level, the current rise leveling signal DQlv1_{—}r is at the low level, and the current fall leveling signal DQlv1_{—}f is at the high level, the flow also proceeds to step S409. In this case, as shown by (A) in FIG. 17, the timing of the read latency deviates from the rising timing of the rise leveling signal DQlv1_{—}r and the fall leveling signal DQlv1_{—}f by a minute amount (i.e., one increase/decrease amount Δd in step S407 or S408); however, Δd is a minute amount and can be neglected, so that the delay amount of the data signal DQij is not set.

Further, if the relationship between the combination of the level of the previous rise leveling signal DQlv1_{—}r and the level of the previous fall leveling signal DQlv1_{—}f and the combination of the level of the current rise leveling signal DQlv1_{—}r and the level of the current fall leveling signal DQlv1_{—}f is other than the foregoing, the flow proceeds to step S406. In this case, the delay amount of the data signal DQij is not set properly, so that the delay amount of the data signal DQij is set.

In step S406 if the current rise leveling signal DQlv1_{—}r is at the high level and the current fall leveling signal DQlv1_{—}f is at the high level, the flow proceeds to step S407; otherwise, the flow proceeds to step S408.

In step S407, the logic 59 increases by Δd the delay amount of the delay circuit 2 which receives the data signal DQij, and the flow proceeds to step S409.

In step S408, the logic 59 decreases the delay amount of the delay circuit 2 which receives the data signal DQij, by Δd, and the flow proceeds to step S409.

In step S409 if the variable j is equal to M, the flow proceeds to step S411. If the variable j is not equal to M, the flow proceeds to step S410.

In step S410, the variable j is incremented, and the flow returns to step S405.

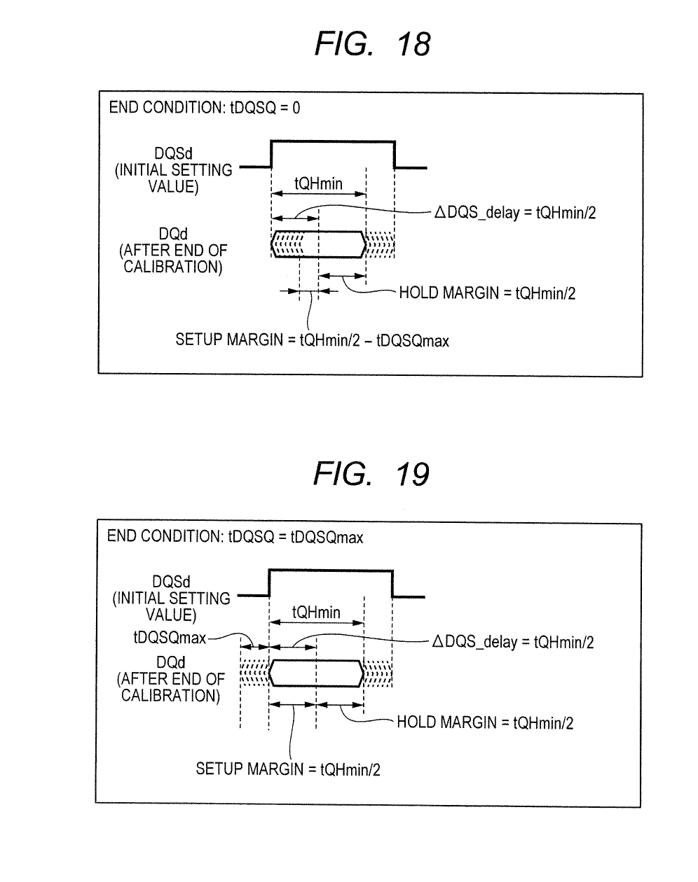

In step S411, the logic 59 adjusts the delay amount of the delay circuit 3 which receives the data strobe signal DQSi. The delay amount is a value obtained by adding tQHmin/2 to the current delay amount, that is, the initial setting value (half the maximum delay amount of the delay circuit 3) in order to secure a setup margin and a hold margin, as shown in FIGS. 18 and 19, where tQHmin is a time from the rising edge of the delay data strobe signal DQSdi to the storage of the head data of the earliest data signal DQdij of the M delay data signals DQdij (j=1 to M) and is determined beforehand by the specification.

In FIGS. 18 and 19, tDQSQ is a time from the rising edge of the delay data strobe signal DQSdi to the start of the head data of the latest data signal DQdij of the M delay data signals DQdij (j=1 to M), and tDQSQmax which is the maximum of tDQSQ is determined beforehand by the specification.

Even in the case where tDQSQ=0 after the end of calibration of DQd as shown in FIG. 18 and also in the case where tDQSQ=tDQSQmax after the end of calibration of DQd as shown in FIG. 19, tQHmin/2 is secured as the setup margin and the hold margin.

### Modification

The present invention is not limited to the above embodiments.

In the second embodiment, the resynchronization clock RCLK generated by the RCLK generator 7 is inputted to the data enable controller 9, and the data enable signal data_en is activated to the high level at the rising timing of the resynchronization clock RCLK, thereby preventing the unstable state (Hi-Z) of the data strobe signal DQS after postamble from being taken in the capture register 4. However, the data enable controller 9 may control the activation of the data enable signal data_en to the high level by a capture control signal other than the resynchronization clock RCLK. The period of the capture control signal is equal to that of the data strobe signal DQS, and the phase of the capture control signal is later than that of the delay data strobe signal DQSd. The data enable controller may activate the data enable signal data_en to the high level on the rising edge of the capture control signal and deactivate the data enable signal data_en to the low level on the falling edge of the delay data strobe signal DQSd.

While the invention made above by the present inventors has been described specifically based on the illustrated embodiments, the present invention is not limited thereto. It is needless to say that various changes and modifications can be made thereto without departing from the spirit and scope of the invention.

What is claimed is:

1. A semiconductor device comprising:
a first register for latching a data signal by a data strobe signal;
a clock generation circuit for generating a resynchronization clock; and
a second register for latching output data of the first register by the resynchronization clock,
wherein the clock generation circuit generates a plurality of delayed clocks having different phases by delaying a core clock which is an operation clock of a CPU, and selects the resynchronization clock whose phase is later than and closest to a phase of the data strobe signal from among the generated delayed clocks and the core clock.

2. The semiconductor device according to claim 1, comprising:
an enable controller for generating an enable signal for controlling the latch of the data signal in the first register,
wherein the enable controller activates the enable signal, based on the resynchronization clock.

3. The semiconductor device according to claim 2,
wherein the first register comprises:
a first flip-flop for latching the data signal by the data strobe signal;
a second flip-flop for latching output of the first flip-flop by an inverted signal of the data strobe signal;
a third flip-flop for latching the data signal by the inverted signal of the data strobe signal; and
a clock gate for controlling supply of the inverted signal of the data strobe signal to the second flip-flop and the third flip-flop,
wherein the clock gate is controlled by the enable signal, and
wherein the enable controller activates the enable signal on a rising edge of the resynchronization clock, and deactivates the enable signal on a falling edge of the data strobe signal.

4. The semiconductor device according to claim 1,
wherein the second register comprises:
a first flip-flop for latching output data of the first register by the resynchronization clock; and
a second flip-flop for latching output data of the first flip-flop by an inverted clock of the resynchronization clock,
wherein if the selected resynchronization clock is a predetermined clock whose phase is earlier than and slightly different from a phase of the core clock, output data of the second flip-flop is transferred to a core clock domain which operates with the core clock, and
wherein if the selected resynchronization clock is not the predetermined clock, the output data of the first flip-flop is transferred to the core clock domain.

5. The semiconductor device according to claim 1,
wherein the clock generation circuit comprises:
a plurality of delay elements to which the core clock is inputted;
a determination unit for determining an optimal clock whose phase is later than and closest to the phase of the data strobe signal from among the core clock and respective clocks outputted from the delay elements; and
a selector for selecting the resynchronization clock from among the core clock and the respective clocks outputted from the delay elements, based on a determination result.

6. The semiconductor device according to claim 5,
wherein the determination unit comprises a plurality of flip-flops corresponding to the respective clocks outputted from the core clock and the delay elements,
wherein the flip-flops latch a first level if a corresponding clock is the optimal clock, and latch a second level if the corresponding clock is not the optimal clock, and
wherein the selector receives outputs of the flip-flops, and selects a clock corresponding to a flip-flop that outputs the first level, as the resynchronization clock.

7. The semiconductor device according to claim 6, wherein the flip-flops latch the first level or the second level, based on a signal for instructing calibration enabling.

8. The semiconductor device according to claim 1, comprising:
a first delay element for delaying a data signal outputted from a memory;
a second delay element for delaying a data strobe signal outputted from the memory; and
a logic which alternately outputs a first read command specifying an address of memory storing a first value and a second read command specifying an address of memory storing a second value and adjusts the delay amount of the first delay element based on data outputted from the second register after a lapse of a read latency from issue of the first read command or the second read command.

9. The semiconductor device according to claim 8, wherein the logic adjusts the delay amount of the second delay element after finishing adjusting the delay amount of the first delay element.

10. A semiconductor device comprising:
a first register for latching a data signal by a data strobe signal; and
an enable controller for generating an enable signal for controlling the latch of the data signal in the first register,
wherein the first register comprises:
a first flip-flop for latching the data signal by the data strobe signal;
a second flip-flop for latching output of the first flip-flop by an inverted signal of the data strobe signal;
a third flip-flop for latching the data signal by the inverted signal of the data strobe signal; and
a clock gate for controlling supply of the inverted signal of the data strobe signal to the second flip-flop and the third flip-flop,
wherein the clock gate is controlled by the enable signal, and
wherein the enable controller activates the enable signal on a rising edge of a capture control signal whose period is identical to a period of the data strobe signal and whose phase is later than a phase of the data strobe signal, and deactivates the enable signal on a falling edge of the data strobe signal.
